(19) United States
(12) Patent Application Publication
(10) Pub. No.: US 2009/0272935 A1
(43) Pub. Date: Nov. 5, 2009

(54) Aligned Carbon Nanotube Bulk Aggregate, Process for Producing The Same and Uses Thereof

(75) Inventors: Kenji Hata, Ibaraki (JP); Don N. Futaba, Ibaraki (JP); Motoo Yumura, Ibaraki (JP); Sumio Iijima, Ibaraki (JP)

Correspondence Address: WENDEROTH, LIND & PONACK, L.L.P., 1030 15th Street, N.W.,, Suite 400 East, Washington, DC, 20005-1503, US

(73) Assignee: National institute of Advanced industrial Science and Technology

(21) Appl. No.: 12/087,450

(22) PCT Filed: Jan. 5, 2007
(86) PCT No.: PCT/JP2007/050050

§ 371 Date: Dec. 3, 2008

(30) Foreign Application Priority Data
Jan. 6, 2006 (JP) 2006-001901

(51) Int. Cl. D01F 9/12; C23C 16/00; C09K 5/00; C09K 3/00; H01B 1/04; C01B 31/08; B32B 9/00; H01G 9/042; H01G 9/058

(52) U.S. Cl. 252/70; 428/195.1; 427/249.1; 252/71; 252/502; 502/416; 423/447.2; 428/408; 361/500; 361/502; 977/750; 977/752

(57) ABSTRACT

An aligned carbon nanotube bulk aggregate of the invention is characterized by consisting of plural carbon nanotubes aligned in a predetermined direction and having a density of 0.2 to 1.5 g/cm³. The carbon nanotube bulk aggregate can be produced by a process of growing carbon nanotubes by chemical vapor deposition (CVD) in the presence of a metal catalyst which comprises growing carbon nanotubes in aligned state in a reaction atmosphere, soaking the obtained carbon nanotubes with a liquid, and then drying the resulting nanotubes. Thus, an aligned carbon nanotube bulk aggregate having a density of 0.2 to 1.5 g/cm³ can be obtained. The invention provides a high density and a high hardness which were not attained in the prior art, and a process for the production of the same.

### TECHNICAL FIELD

The present invention relates to an aligned carbon nanotube bulk aggregate and a process for producing the same, and to uses thereof. In more detail, the present invention relates to an aligned carbon nanotube bulk aggregate capable of realizing high density, high hardness, high purity, high specific surface area, large scaling and patterning, an aspect of which has not hitherto been achieved, and to a process for producing the same and to use thereof.

### BACKGROUND ART

Regarding carbon nanotubes (CNT) that are expected for development to functional materials as novel electronic device materials, optical device materials, electrically conductive materials, biotechnology-related materials and others, energetic investigations of their yield, quality, use, mass productivity and production method are being promoted.

For putting carbon nanotubes into practical use for the above-mentioned functional materials, one method may be taken into consideration, which comprises preparing a bulk aggregate of a large number of carbon nanotubes, large-scaling the size of the bulk aggregate, and improving its properties such as the purity, the specific surface area, the electric conductivity, the density and the hardness to thereby make it patternable in a desired shape. In addition, the mass productivity of carbon nanotubes must be increased greatly.

To solve the above-mentioned problems, the inventors of this application have assiduously studied and, as a result, have found that, in a process of chemical vapor deposition (CVD) where carbon nanotubes are grown in the presence of a metal catalyst, when a very small amount of water vapor is added to the reaction atmosphere, then an aligned carbon nanotube bulk aggregate having a high purity and having extremely large-scaled as compared with that in conventional methods can be obtained, and have reported it in Non-Patent Document 1, etc.

### Non-Patent Document 1: Kenji Hata et al., Water-Assisted Highly Efficient Synthesis of Impurity-Free Single-Walled Carbon Nanotubes, SCIENCE, 2004.11.19, Vol. 306, pp. 1362-1364.

### DISCLOSURE OF THE INVENTION

### Problems to be Solved by the Invention

The aligned carbon nanotube bulk aggregate reported in the above-mentioned Non-Patent Document 1 has, for example, a purity before purification of 99.98 mass % and a specific surface area of about 1000 m²/g, and has a height (length) of about 2.5 mm or so, which comprises a large number of single-walled carbon nanotubes growing as aggregated.

However, in order to apply the aligned carbon nanotube bulk aggregate as a functional material having much better properties, its strength and hardness must be further improved since the density of the structure of the above-mentioned report must is about 0.03 g/cm³ or so and it is mechanically brittle. In addition, there is room for further investigation of the structure in point of the handlability and the workability thereof.

With the background described above, an object of the present invention is to provide an aligned carbon nanotube bulk aggregate capable of realizing unpredicted high density and high hardness, and a process for producing the same.

Another object of the present invention is to provide an aligned carbon nanotube bulk aggregate having a high purity, a large specific surface area and a high electric conductivity, excellent in mass productivity and capable of attaining large scaling in a simplified manner, and to provide a process for producing the same.

Further object of the present invention is to provide an aligned carbon nanotube bulk aggregate having excellent handlability and workability, and to provide a process for producing the same. Still another object of the present invention is to provide an aligned carbon nanotube bulk aggregate capable of attaining patterning, and a process for producing the same and uses thereof.

For the purpose of solving the foregoing problems, this application provides the following inventions.

(1) An aligned carbon nanotube bulk aggregate in which plural carbon nanotubes are aligned in a predetermined direction and which has a density of from 0.2 to 1.5 g/cm³.

(2) The aligned carbon nanotube bulk aggregate according to the above (1), wherein the carbon nanotubes are single-walled carbon nanotubes.

(3) The aligned carbon nanotube bulk aggregate according to the above (1), wherein the carbon nanotubes are double-walled carbon nanotubes.

(4) The aligned carbon nanotube bulk aggregate according to the above (1), wherein the carbon nanotubes are a mixture of single-walled carbon nanotubes and double-walled or more multi-walled carbon nanotubes.

(5) The aligned carbon nanotube bulk aggregate according to any one of the above (1) to (4), which has a purity of at least 98 mass %.

(6) The aligned carbon nanotube bulk aggregate according to any one of the above (1) to (5), which has a specific surface area of from 600 to 2600 m²/g.

(7) The aligned carbon nanotube bulk aggregate according to any one of the above (1) to (5), which is unopened and which has a specific surface area of from 600 to 1300 m²/g.

(8) The aligned carbon nanotube bulk aggregate according to any one of the above (1) to (5), which is opened and which has a specific surface area of from 1300 to 2600 m²/g.

(9) The aligned carbon nanotube bulk aggregate according to any one of the above (1) to (8), which is a mesoporous material having a packing ratio of from 5 to 50%.

(10) The aligned carbon nanotube bulk aggregate according to any one of the above (1) to (9), which has a mesopore diameter of from 1.0 go 5.0 nm.

(11) The aligned carbon nanotube bulk aggregate according to any one of the above (1) to (10), which has a Vickers hardness of from 5 to 100 HV.

(12) The aligned carbon nanotube bulk aggregate according to any one of the above (1) to (11), which is vertically aligned or horizontally aligned on a substrate.

(13) The aligned carbon nanotube bulk aggregate according to any one of the above (1) to (11), which is aligned on a substrate in the direction oblique to the substrate surface.

(14) The aligned carbon nanotube bulk aggregate according to any one of the above (1) to (13), which has anisotropy between the alignment direction and the direction vertical thereto, in at least any of optical properties, electric properties, mechanical properties and thermal properties.

(15) The aligned carbon nanotube bulk aggregate according to any one of the above (1) to (14), wherein the degree of anisotropy between the alignment direction and the direction vertical thereto is at most ⅕ in terms of the ratio of the small value to the large value.

(16) The aligned carbon nanotube bulk aggregate according to any one of the above (1) to (15), wherein the intensity ratio of any of the (100), (110) and (002) peaks in the alignment direction and in the direction vertical thereto in X-ray diffraction is from ½ to 1/100 in terms of the ratio of the small value to the large value.

(17) The aligned carbon nanotube bulk aggregate according to any one of the above (1) to (16), wherein the shape of the bulk aggregate is patterned in a predetermined shape.

(18) The aligned carbon nanotube bulk aggregate according to the above (17), wherein the shape is a thin film.

(19) The aligned carbon nanotube bulk aggregate according to the above (17), wherein the shape is a columnar one having a circular, oval or n-angled cross section (n is an integer of at least 3).

(20) The aligned carbon nanotube bulk aggregate according to the above (17), wherein the shape is a block.

(21) The aligned carbon nanotube bulk aggregate according to the above (17), wherein the shape is a needle-like one.

(22) A process for producing an aligned carbon nanotube bulk aggregate through chemical vapor deposition (CVD) of carbon nanotubes in the presence of a metal catalyst, wherein plural carbon nanotubes are grown, as aligned, in a reaction atmosphere, and then the resulting plural carbon nanotubes are exposed to liquid and dried thereby giving an aligned carbon nanotube bulk aggregate having a density of from 0.2 to 1.5 g/m³.

(23) The process for producing an aligned carbon nanotube bulk aggregate according to the above (22), which is for producing an aligned carbon nanotube bulk aggregate where the carbon nanotubes are single-walled carbon nanotubes.

(24) The process for producing an aligned carbon nanotube bulk aggregate according to the above (22), which is for producing an aligned carbon nanotube bulk aggregate where the carbon nanotubes are double-walled carbon nanotubes.

(25) The process for producing an aligned carbon nanotube bulk aggregate according to the above (22), which is for producing an aligned carbon nanotube bulk aggregate where the carbon nanotubes are a mixture of single-walled carbon nanotubes and double-walled or more multi-walled carbon nanotubes.

(26) The process for producing an aligned carbon nanotube bulk aggregate according to any one of the above (22) to (25), which is for producing an aligned carbon nanotube bulk aggregate having a purity of at least 98 mass %.

(27) The process for producing an aligned carbon nanotube bulk aggregate according to any one of the above (22) to (26), which is for producing an aligned carbon nanotube bulk aggregate having a specific surface area of from 600 to 2600 m²/g.

(28) The process for producing an aligned carbon nanotube bulk aggregate according to any one of the above (22) to (26), which is for producing an aligned carbon nanotube bulk aggregate that is unopened and has a specific surface area of from 600 to 1300 m² μg.

(29) The process for producing an aligned carbon nanotube bulk aggregate according to any one of the above (22) to (26), which is for producing an aligned carbon nanotube bulk aggregate that is opened and has a specific surface area of from 1300 to 2600 m²/g.

(30) The process for producing an aligned carbon nanotube bulk aggregate according to any one of the above (22) to (29), which is for producing an aligned carbon nanotube bulk aggregate that has anisotropy between the alignment direction and the direction vertical thereto, in at least any of optical properties, electric properties, mechanical properties and thermal properties.

(31) The process for producing an aligned carbon nanotube bulk aggregate according to any one of the above (22) to (30), which is for producing an aligned carbon nanotube bulk aggregate of such that the degree of anisotropy between the alignment direction and the direction vertical thereto is at most ⅕ in terms of the ratio of the small value to the large value.

(32) The process for producing an aligned carbon nanotube bulk aggregate according to any one of the above (22) to (31), which is for producing an aligned carbon nanotube bulk aggregate of such that the intensity ratio of any of the (100), (110) and (002) peaks in the alignment direction and in the direction vertical thereto in X-ray diffraction is from ½ to 1/100 in terms of the ratio of the small value to the large value.

(33) The process for producing an aligned carbon nanotube bulk aggregate according to any one of the above (22) to (32), which is for producing an aligned carbon nanotube bulk aggregate as patterned in any desired shape.

(34) The process for producing an aligned carbon nanotube bulk aggregate according to the above (33), which is for producing an aligned carbon nanotube bulk aggregate having a thin filmy shape.

(35) The process for producing an aligned carbon nanotube bulk aggregate according to the above (33), which is for producing an aligned carbon nanotube bulk aggregate having a columnar shape that has a circular, oval or n-angled cross section (n is an integer of at least 3).

(36) The process for producing an aligned carbon nanotube bulk aggregate according to the above (33), which is for producing an aligned carbon nanotube bulk aggregate having a block shape.

(37) The process for producing an aligned carbon nanotube bulk aggregate according to the above (33), which is for producing an aligned carbon nanotube bulk aggregate having a needle-like shape.

(38) A heat dissipation material comprising the aligned carbon nanotube bulk aggregate according to any one of the above (1) to (21).

(39) An article provided with the heat dissipation material according to the above (38).

(40) A heat conductor comprising the aligned carbon nanotube bulk aggregate according to any one of the above (1) to (21).

(41) An article provided with the heat conductor according to the above (40).

(42) An electric conductor comprising the aligned carbon nanotube bulk aggregate according to any one of the above (1) to (21).

(43) An article provided with the electric conductor according to the above (42).

(44) An electrode material comprising the aligned carbon nanotube bulk aggregate according to any one of the above (1) to (21).

(45) A cell wherein the electrode comprises the electrode material according to the above (44).

(46) A capacitor or supercapacitor wherein the electrode material comprises the aligned carbon nanotube bulk aggregate according to any one of the above (1) to (21).

(47) An adsorbent comprising the aligned carbon nanotube bulk aggregate according to any one of the above (1) to (21).

(48) A gas absorbent comprising the aligned carbon nanotube bulk aggregate according to any one of the above (1) to (21).

(49) A flexible electrically conductive heater comprising the aligned carbon nanotube bulk aggregate according to any one of the above (1) to (21).

### EFFECT OF THE INVENTION

The aligned carbon nanotube bulk aggregate of the present invention is an unprecedented high-strength aligned carbon nanotube bulk aggregate, of which the density is at least about 20 times that of the aligned carbon nanotube bulk aggregate that the inventors of this application proposed in Non-Patent Reference 1, and is extremely high (at least 0.2 g/Cm³), and of which the hardness is at least about 100 times that of the previous one and is extremely large; and this is not a material having a soft feeling but is a novel material that exhibits a phase of so-called “solid”.

The aligned carbon nanotube bulk aggregate of the present invention is a highly purified one and its contamination with catalyst and side product is inhibited. Its specific surface area is from 600 to 2600 m²/g or so, and is on the same level as that of typical porous materials, activated carbon and SBA-15. Though ordinary porous materials are insulators, the aligned carbon nanotube bulk aggregate of the invention has high electric conductivity and, when formed into a sheet, it is flexible. When the aligned carbon nanotube bulk aggregate produced in Non-Patent Document 1 is formed into an aligned carbon nanotube bulk structure, then a material having a carbon purity of at least 99.98% could be produced.

The aligned carbon nanotube bulk aggregate of the present invention has excellent handlability and workability, and can be readily worked Into any desired shape.

The aligned carbon nanotube bulk aggregate of the present invention has excellent properties of purity, density, hardness, specific surface area, electric conductivity and workability, and can be large-scaled, and therefore has various applications for heat dissipation materials, heat conductors, electric conductors, electrode materials, batteries, capacitors, supercapacitors, adsorbents, gas storages, flexible beaters, etc.

Further, according to the process for producing the aligned carbon nanotube bulk aggregate of the present invention, the aligned carbon nanotube bulk aggregate having the above-mentioned excellent properties can be produced with high mass-productivity in a simplified manner with chemical vapor deposition (CVD).

### BRIEF DESCRIPTION OF THE DRAWINGS

FIG. 1 shows electron microscopic (SEM) images of an aligned carbon nanotube bulk aggregate.

FIG. 2 shows X-ray diffraction data of an aligned carbon nanotube bulk aggregate.

FIG. 3 shows an example of low-angle X-ray diffraction data in a case where an aligned carbon nanotube bulk aggregate is irradiated with X rays in the direction vertical to the alignment direction.

FIG. 4 shows liquid nitrogen adsorption/desorption isothermal curves of an aligned carbon nanotube bulk aggregate.

FIG. 5 shows the adsorption per unit volume of an aligned carbon nanotube bulk aggregate.

FIG. 6 shows a relation between the adsorption per unit volume of an aligned carbon nanotube bulk aggregate and the specific surface area per unit weight thereof.

FIG. 7 shows examples of Raman spectrometry of an aligned carbon nanotube bulk aggregate.

FIG. 8 shows the appearance of plural aligned carbon nanotubes before exposure to liquid and after exposure to liquid followed by drying.

FIG. 9 shows images indicating the change the appearance of plural aligned carbon nanotubes before exposure to liquid and after exposure to liquid followed by drying.

FIG. 10 shows Raman spectrum data after exposure of plural aligned carbon nanotubes to water followed by drying them.

FIG. 11 is a model showing the shape control of an aligned carbon nanotube bulk aggregate.

FIG. 12 is a schematic view showing one example of a heat dissipation material comprising an aligned carbon nanotube bulk aggregate.

FIG. 13 is a schematic view showing one example of a heat exchanger comprising an aligned carbon nanotube bulk aggregate.

FIG. 14 shows current/voltage characteristics of an aligned carbon nanotube bulk aggregate (to which a high current is applied).

FIG. 15 shows current/voltage characteristics of an aligned carbon nanotube bulk aggregate (to which a low current is applied).

FIG. 16 is a schematic view showing one example of a supercapacitor comprising an aligned carbon nanotube bulk aggregate.

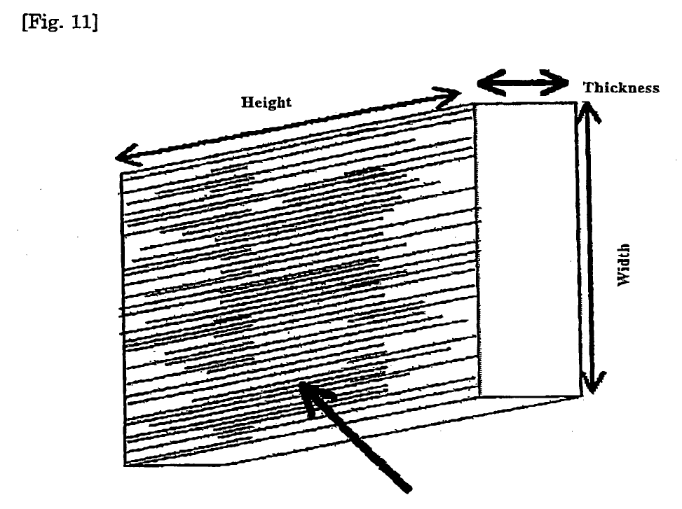

FIG. 11 is a conceptual view schematically showing a case of application of an aligned carbon nanotube bulk aggregate to a hydrogen storage.

FIG. 18 shows flexible electroconductive heaters comprising an aligned carbon nanotube bulk aggregate.

FIG. 19 shows cyclic voltamography data In a case of application of an aligned carbon nanotube bulk aggregate to a supercapacitor.

### BEST MODE FOR CARRYING OUT THE INVENTION

The present invention has the above-mentioned characteristics, and its embodiments will be described hereinunder.

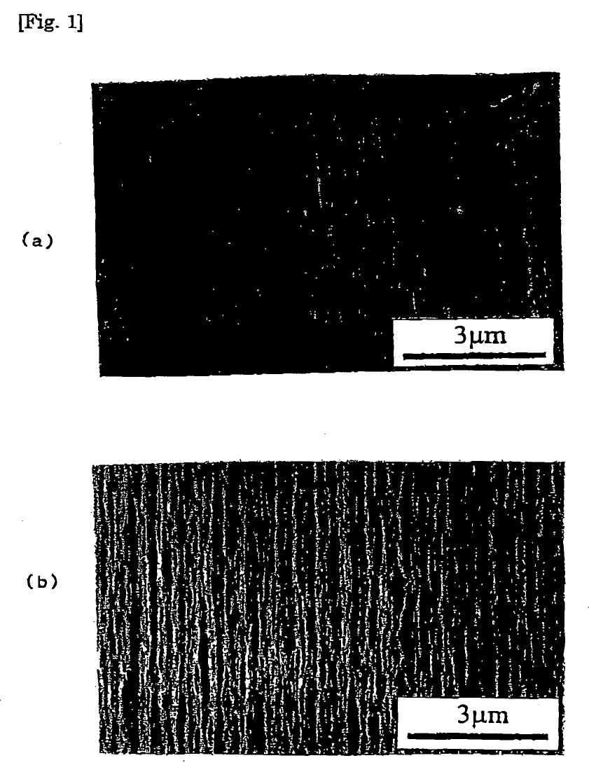

The aligned carbon nanotube bulk aggregate of the present invention is characterized in that the plural carbon nanotubes therein aggregate together, the neighboring carbon nanotubes strongly bond to each other by van der Waals force, and these carbon nanotubes are aligned in a predetermined direction, and that the lowermost limit of the density of the aggregate is 0.2 g/m³, preferably 0.3 g/m³, more preferably 0.4 g/m³, and the uppermost limit of the density thereof is 1.0 g/m³, preferably 1.2 g/m³, more preferably 1.5 g/m³. When the density of the aligned carbon nanotube bulk aggregate is lower than the above-mentioned range, then the aggregate is mechanically brittle and could not have sufficient mechanical strength; but when too high, then the specific surface area of the aggregate may decrease. The aligned carbon nanotube bulk aggregate having a density within the range is not a material having a soft feeling like the aligned carbon nanotube bulk aggregate produced in Non-Patent Document 1, but has a phase of so-called “solid”. FIG. 1 shows an electron microscopic (SEM) image (a) of an aligned carbon nanotube bulk aggregate of the present invention, as compared with a photographic image (b) of an aligned carbon nanotube bulk aggregate produced in Non-Patent Document 1 (hereinafter this may be referred to as previously-proposed aligned carbon nanotube bulk aggregate). In this example, the density of the aligned carbon nanotube bulk aggregate of the present invention is about 20 times larger than the density of the previously-proposed aligned carbon nanotube bulk aggregate.

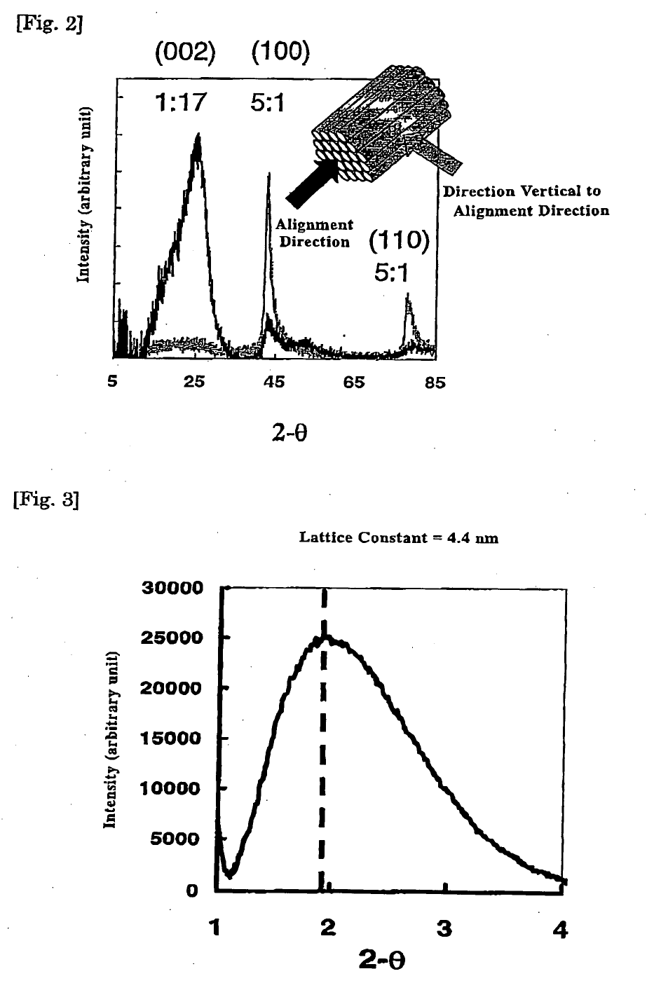

FIG. 2 shows X-ray diffraction data of an aligned carbon nanotube bulk aggregate of the present invention. In the drawing, L indicates the data of the aligned carbon nanotube bulk aggregate irradiated with X rays in the alignment direction; and T indicates the data thereof irradiated with X rays in the direction vertical to the alignment direction. Samples were so produced that the thickness of the aligned carbon nanotube bulk aggregate is the same both in the T direction and the L direction, and compared with each other. The intensity ratio of the (100), (110) and (002) diffraction peaks in the L direction and the T direction of the X-ray diffraction data confirms-good alignment. Regarding the (100) and (110) peaks, the intensity is higher In the case of X ray irradiation In the direction vertical to the alignment direction (T direction) than in the case of X ray irradiation in the alignment direction (L direction); and the intensity ratio is, for example, in the case of FIG. 2, 5:1 at both the (100) peak and the (110) peak. This is because, in the case of X ray irradiation in the direction vertical to the alignment direction (T direction), the graphite lattices constituting carbon nanotubes are seen. On the contrary, in the case of the (002) peak by X ray Irradiation in the alignment direction (L direction), the intensity is higher than that in the case of X ray irradiation in the direction vertical to the alignment direction (T direction); and the intensity ratio is, for example, in the case of FIG. 2, 17:1. This is because, in the case of X ray irradiation in the alignment direction (L direction), the contact points of carbon nanotubes are seen.

FIG. 3 shows an example of low-angle X-ray diffraction data in a case where an aligned carbon nanotube bulk aggregate of the present invention is irradiated with X rays in the alignment direction (L direction). It is known that the case of this example is a structure having a lattice constant of about 4.4 nm.

The carbon nanotubes that constitute the aligned carbon nanotube bulk aggregate of the present invention may be single-walled carbon nanotubes or double-walled carbon nanotubes, or may also be in the form of a mixture of single-walled carbon nanotubes and double-walled or more multi-walled carbon nanotubes in a suitable ratio.

Regarding the production process for the aligned carbon nanotube bulk aggregate of the present invention, the aggregate may be produced according to the process of the invention of above-mentioned [22] to [37], and its details are described hereinunder. In case where the aligned carbon nanotube bulk aggregate obtained according to the process is used in an application in which the purity thereof is taken into consideration, its purity can be preferably at least 98 mass %, more preferably at least 99 mass %, even more preferably at least 99.9 mass %. When the production process that the inventors of this application proposed in Non-Patent Document 1 is utilized, then an aligned carbon nanotube bulk aggregate having a high purity as above can be obtained even though it is not processed for purification. The aligned carbon nanotube bulk aggregate having such a high purity contains few impurities, and therefore it may exhibit the properties intrinsic to carbon nanotubes.

The purity as referred to in this description is represented by mass % of carbon nanotubes in a product. The impurity may be obtained from the data of elementary analysis with fluorescent X rays.

A preferred range of the height (length: dimension of carbon nanotubes in the lengthwise direction) of the aligned carbon nanotube bulk aggregate of the present invention varies, depending on the application thereof. In case where it is used as a large-scaled one, the lowermost limit of the range is preferably 5 μm, more preferably 10 μm, even more preferably 20 μm; and the uppermost limit thereof is preferably 2.5 mm, more preferably 1 cm, even more preferably 10 cm.

The aligned carbon nanotube bulk aggregate of the present invention has an extremely large specific surface area, and its preferred value varies depending on the use of the aggregate. For applications that require a large specific surface area, the specific surface area is preferably from 600 to 2600 m²/g, more preferably from 800 to 2600 m²/g, even more preferably from 1000 to 2600 m²/g. The carbon nanotube material of the present invention that is unopened preferably has a specific surface area of from 600 to 1300 m²/g, more preferably from 800 to 1300 m²/g, even more preferably from 1000 to 1300 m²/g. The carbon nanotube material of the present invention that is opened preferably has a specific surface area of from 1300 to 2600 m²/g, more preferably from 1500 to 2600 m²/g, even more preferably from 1700 to 2600 m²/g.

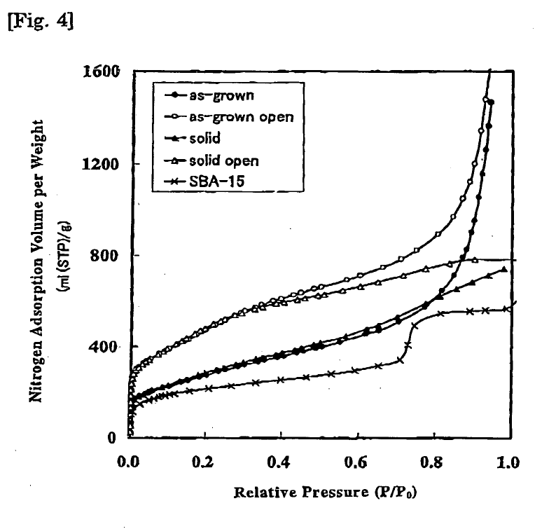

The specific surface area may be determined through computation of adsorption/desorption isothermal curves. One example is described with reference to 50 mg of an aligned carbon nanotube bulk aggregate of the present invention. Using Nippon Bell's BELSORP-MINI, liquid nitrogen adsorption/desorption isothermal curves were drawn at 77 K (see FIG. 4). (The adsorption equilibrium time was 600 seconds). The specific surface area was computed from the adsorption/desorption isothermal curves, and it was about 1100 m² μg. In the relative pressure region of at most 0.5, the adsorption/desorption isothermal curves showed linearity, and this confirms that the carbon nanotubes in the aligned carbon nanotube bulk aggregate are unopened.

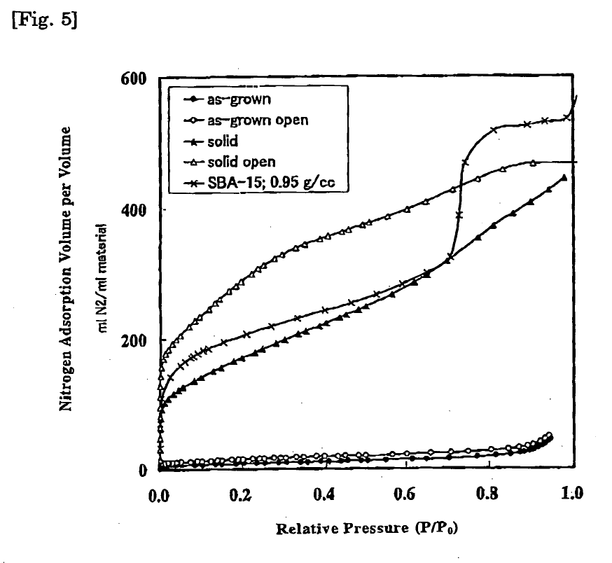

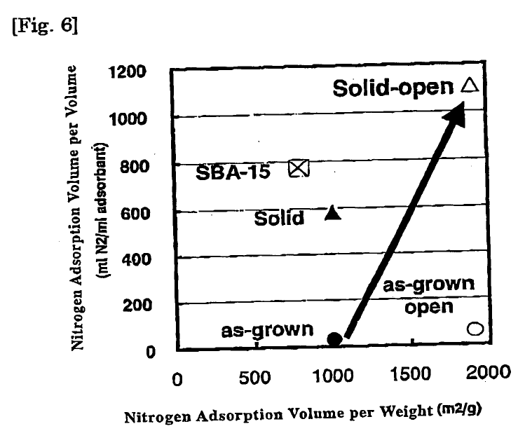

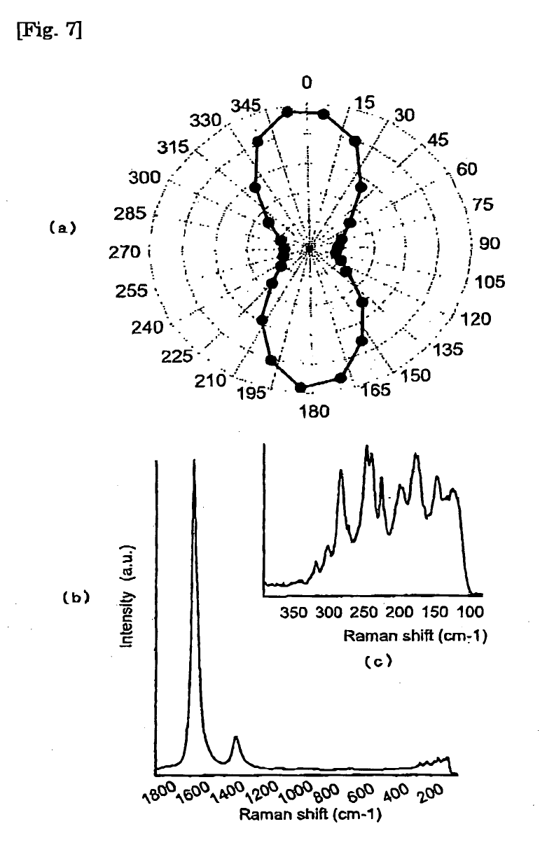

When the aligned carbon nanotube bulk aggregate of the present invention is processed for opening, then the top end of the carbon nanotube is opened to thereby increase the specific surface area thereof. In FIG. 4, ▴ indicates the data of an unopened aligned carbon nanotube bulk aggregate of the present invention; Δ indicates the data of an opened one thereof; indicates the data of an unopened, previously-proposed aligned carbon nanotube bulk aggregate; O indicates the data of an opened one thereof; x indicates the data of mesoporous silica (SBA-15). The opened aligned carbon nanotube bulk aggregate of the present invention realized an extremely large specific surface area of about 1900 w²/g. FIG. 5 shows the adsorption per unit volume; and FIG. 6 shows a relation between the adsorption per unit volume and the specific surface area per unit weight. From these drawings, it is known that the aligned carbon nanotube bulk aggregate of the present invention has a large specific surface area and good adsorption capability. For the opening treatment, employable is a dry process of treatment with oxygen, carbon dioxide or water vapor. In case where a wet process is employable for it, it may comprise treatment with an acid, concretely refluxing treatment with hydrogen peroxide or cutting treatment with high-temperature hydrochloric acid.

The aligned carbon nanotube bulk aggregate having such a large specific surface area exhibits great advantages in various applications of electrode materials, batteries, capacitors, supercapacitors, electron emission devices, field emission type displays, adsorbents, gas storages, etc. When the specific surface area is too small and when the aggregate having such a small specific surface area is used in the above-mentioned applications, then the devices could not have desired properties. The uppermost limit of the specific surface area is preferably as high as possible, but is theoretically limited.

The aligned carbon nanotube bulk aggregate of the present invention may be in the form of a mesoporous material having a packing ratio of from 5 to 50%, more preferably from 10 to 40%, even more preferably from 10 to 30%. In this case, the material preferably contains those having a mesopore diameter of from 1.0 to 5.0 nm. The mesopores in this case are defined by the size thereof in the aligned carbon nanotube bulk aggregate. When the carbon nanotubes in the aligned carbon nanotube bulk aggregate are opened through oxidation treatment or the like as in Example 6, and when liquid nitrogen adsorption/desorption isothermal curves of the structure are prepared and SP plots are obtained from the adsorption curves, then the mesopores corresponding to the size of the carbon nanotubes may be computed. On the contrary, from the above-mentioned experimental facts, it is known that the opened aligned carbon nanotube bulk aggregate can function as a mesopore material. The packing ratio in the mesopores may be defined by the coating ratio of the carbon nanotubes. When the packing ratio or the mesopore size distribution falls within the above range, then the aligned carbon nanotube bulk aggregate is favorably used in applications of a mesoporous material and may have a desired strength.

An ordinary mesoporous material is an insulator, but the aligned carbon nanotube bulk aggregate of the present invention has high electric conductivity and, when formed into a sheet, it is flexible.

The Vickers hardness of the aligned carbon nanotube bulk aggregate of the present invention is preferably from 5 to 100 HV. The Vickers hardness falling within the range is a sufficient mechanical strength comparable to that of typical mesoporous materials, active carbon and SBA-15, and exhibits great advantages in various applications that require mechanical strength.

The aligned carbon nanotube bulk aggregate of the present invention may be provided on a substrate, or may not be thereon. In case where it is provided on a substrate, it may be aligned vertically to the surface of the substrate, or horizontally or obliquely thereto.

Further, the aligned carbon nanotube bulk aggregate of the present invention preferably shows anisotropy between the alignment direction and the direction vertical thereto, in at least any of optical properties, electric properties, mechanical properties and thermal properties. The degree of anisotropy of the aligned carbon nanotube bulk aggregate between the alignment direction and the direction vertical thereto is preferably at most ⅓, more preferably at most 115, even more preferably at most 1/10. The lowermost limit may be about 1/100. Also preferably, the intensity ratio of any of the (100), (110) and (002) peaks in the alignment direction and in the direction vertical thereto in X-ray diffraction is from ½ to 1/100 in terms of the ratio of the small value to the large value. FIG. 2 shows one example of the case. Such a large anisotropy of, for example, optical properties makes it possible to apply the structure to polarizers that utilize the polarization dependency of light absorbance or light transmittance. The anisotropy of other properties also makes it possible to apply the structure to various articles that utilize the Individual anisotropy.

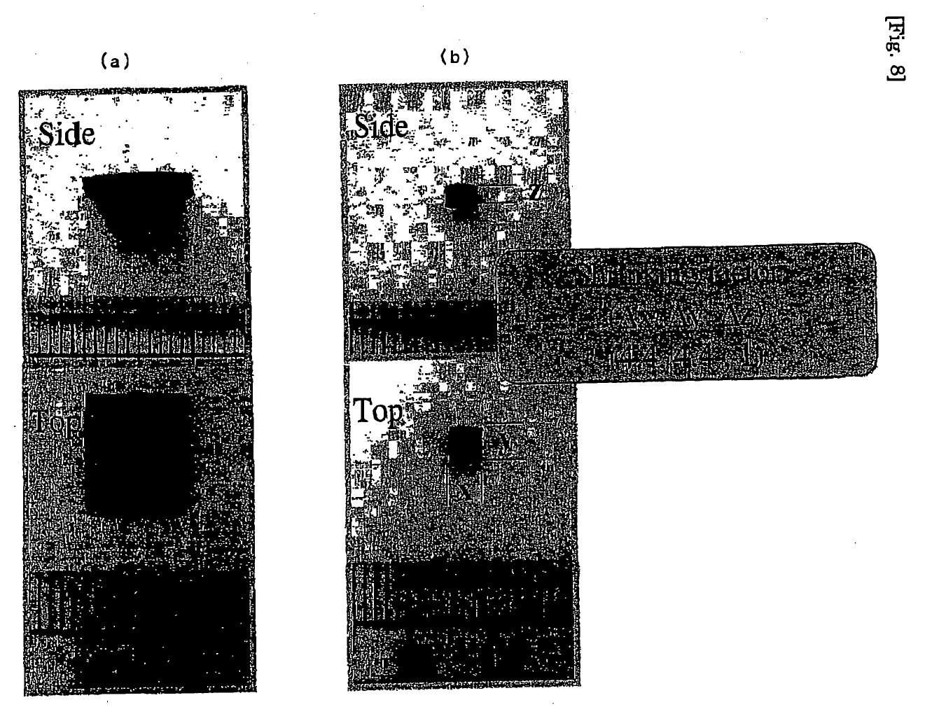

The quality of the carbon nanotubes (filaments) in the aligned carbon nanotube bulk aggregate can be evaluated through Raman spectrometry. One example of Raman spectrometry is shown in FIG. 7. In FIG. 7, (a) shows the anisotropy of Raman G band; and (b) and (c) show data of Raman G band. From the drawings, it is known that the G band having a sharp peak is seen at 1592 kayser indicating the presence of a graphite crystal structure. In addition, it is also known that the D band is small therefore indicating the presence of a high-quality graphite layer with few defects. On the short wavelength side, seen are RBM modes caused by plural single-walled carbon nanotubes, and it is known that the graphite layer comprises a single-walled carbon nanotubes. These confirm the existence of high-quality single-walled carbon nanotubes in the aligned carbon nanotube bulk aggregate of the present invention. Further, it is known that the Raman G band anisotropy differs by 6.8 times between the alignment direction and the direction vertical thereto.

Further, the aligned carbon nanotube bulk aggregate of the present invention may be patterned in a predetermined shape.

The shape includes, for example, thin films, as well as any desired blocks such as columns having a circular, oval or n-angled cross section (n is an integer of at least 3), or cubic or rectangular solids, and needle-like solids (including sharp, thin and long cones). The patterning method is described hereinunder.

Next described is a process for producing the aligned carbon nanotube bulk aggregate of the present invention.

The process for producing the aligned carbon nanotube bulk aggregate of the present invention is a process of chemical vapor deposition (CVD) of carbon nanotubes in the presence of a metal catalyst, which is characterized in that plural carbon nanotubes are grown, as aligned, in a reaction atmosphere, and then the resulting plural carbon nanotubes are exposed to liquid and dried thereby giving an aligned carbon nanotube bulk aggregate having a density of from 0.2 to 1.5 g/m³.

First described is the method of aligned growth of plural carbon nanotubes through CVD.

As the carbon compound for the starting carbon source in CVD, usable are hydrocarbons like before, and preferred are lower hydrocarbons such as methane, ethane, propane, ethylene, propylene, acetylene. One or more of these may be used, and use of lower alcohols such as methanol or ethanol and low-carbon oxygen-containing compounds such as acetone or carbon monoxide may also be taken into consideration within an acceptable range for the reaction condition.

The atmospheric gas for reaction may be any one that does not react with carbon nanotubes and is inert at the growing temperature. Its examples include helium, argon, hydrogen, nitrogen, neon, krypton, carbon dioxide, chloride, and their mixed gases; and especially preferred are helium, argon, hydrogen and their mixed gases.

The atmospheric pressure in reaction may be any one falling within a pressure range within which carbon nanotubes can be produced, and is preferably from 10² Pa to 107 Pa (100 atmospheres), more preferably from 10⁴ Pa to 3>10⁵ Pa (3 atmospheres), even more preferably from 5×10 Pa to 9×10 Pa.

As so mentioned in the above, a metal catalyst is made to exist in the reaction system, and the catalyst may be any suitable one heretofore used in production of carbon nanotubes. For example, it includes thin film of iron chloride, thin film of iron formed by sputtering, thin film of iron-molybdenum, thin film of alumina-iron, thin film of alumina-cobalt, thin film of alumna-iron-molybdenum, etc.

The amount of the catalyst may fall within any range heretofore employed in production of carbon nanotubes. For example, when an iron metal catalyst is used, then its thickness is preferably from 0.1 μm to 100 nm, more preferably from 0.5 nm to 5 nm, even more preferably from 1 nm to 2 nm.

Regarding the catalyst positioning, employable is any method of positioning the metal catalyst having a thickness as above, suitable for sputtering deposition.

The temperature in the growth reaction in CVD may be suitably determined in consideration of the reaction pressure, the metal catalyst, the carbon source material, etc.

According to the process of the present invention, a catalyst may be disposed on a substrate, and plural carbon nanotubes may be grown, as aligned vertically to the substrate surface. In this case, any substrate heretofore used in production of carbon nanotubes is employable, for example, including the following:

(1) Metals and semiconductors such as iron, nickel, chromium, molybdenum, tungsten, titanium, aluminium, manganese, cobalt, copper, silver, gold, platinum, niobium, tantalum, lead, zinc, gallium, germanium, indium, gallium, germanium, arsenic, indium, phosphorus, antimony; their alloys; and oxides of those metals and alloys.

(2) Thin films, sheets, plates, powders and porous materials of the above-mentioned metals, alloys and oxides.

(3) Non-metals and ceramics such as silicon, quartz, glass, mica, graphite, diamond; their wafers and thin films.

For the method of patterning the catalyst, employable is any suitable method capable of directly or indirectly patterning the catalyst metal. It may be a wet process or a dry process; and for example, herein employable are patterning with mask, patterning by nano-inprinting, patterning through soft lithography, patterning by printing, patterning by plating, patterning by screen printing, patterning through lithography, as well as a method of patterning some other material capable of selectively adsorbing a catalyst on a substrate and then making the other material selectively adsorb a catalyst thereby forming a pattern. Preferred methods are patterning through lithography, metal deposition photolithography with mask, electron beam lithography, catalyst metal patterning through electron beam deposition with mask, and catalyst metal patterning through sputtering with mask.

According to the process of the present invention, an oxidizing agent such as water vapor may be added to the reaction atmosphere described in Non-Patent Document 1 thereby growing a large quantity of aligned single-walled carbon nanotubes. Needless-to-say, the invention should not be limited to the process, in which, therefore, any other various processes may be employed.

In the manner as above, an aligned carbon nanotube bulk aggregate before exposed to liquid and dried may be obtained.

The method of peeling the aligned carbon nanotube bulk aggregate from the substrate may be a method of peeling it from the substrate physically, chemically or mechanically. For example, herein employable are a method of peeling it by the action of an electric field, a magnetic field, a centrifugal force or a surface tension; a method of mechanically peeling it directly from the substrate; and a method of peeling it from the substrate under pressure or heat. One simple peeling method comprises picking it up directly from the substrate with tweezers and peeling it. More preferably, it may be cut off from the substrate by the use of a thin cutting tool such as cutter blade. Further, it may be peeled by suction from the substrate, using a vacuum pump or a vacuum cleaner. After peeled, the catalyst may remain on the substrate, and it may be again used in the next step of growing carbon nanotubes. Needless-to-say, the aligned carbon nanotube bulk aggregate formed on the substrate may be directly processed as it is in the next step.

According to the process of the present invention, plural aligned carbon nanotubes formed in the manner as above are exposed to liquid and then dried thereby giving the intended aligned carbon nanotube bulk aggregate.

The liquid to which plural aligned carbon nanotubes are exposed is preferably one that has an affinity to carbon nanotubes and does not remain in the carbon nanotubes wetted with it and then dried. The liquid of the type usable herein includes, for example, water, alcohols (isopropanol, ethanol, methanol), acetones (acetone), hexane, toluene, cyclohexane, DMF (dimethylformamide), etc.

For exposing plural aligned carbon nanotubes to the above-mentioned liquid, for example, employable are a method comprising dropwise applying the liquid droplets little by little onto the upper surface of the aligned carbon nanotube aggregate and repeating the operation until the aligned carbon nanotube aggregate is finally completely enveloped by the liquid droplets; a method comprising vetting the surface of the substrate with the liquid by the use of pipette, then infiltrating the liquid into the aligned carbon nanotube aggregate from the point at which the aggregate is kept in contact with the substrate, thereby wetting entirely the aligned carbon nanotube aggregate; a method comprising vaporizing the liquid and exposed the entire aligned carbon nanotube aggregate with the vapor in a predetermined direction; a method comprising spraying the liquid onto the aligned carbon nanotube aggregate so as to wet it with the liquid. For drying the aligned carbon nanotube aggregate after wetted with the liquid, for example, employable is a method of spontaneous drying at room temperature, vacuum drying, or heating on a hot plate or the like.

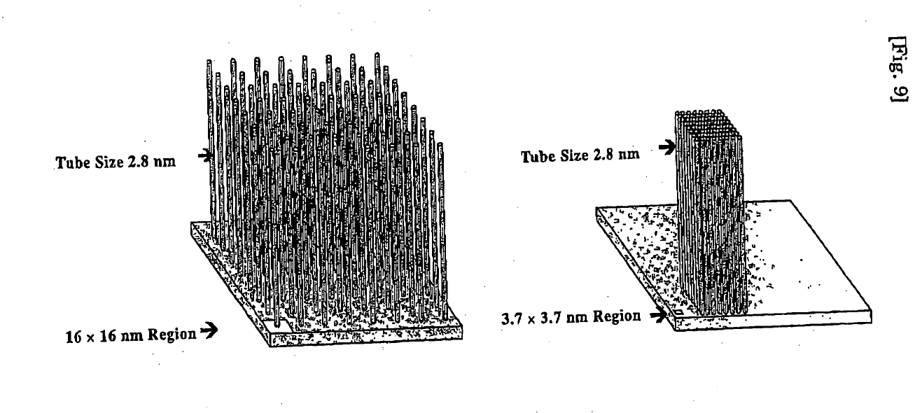

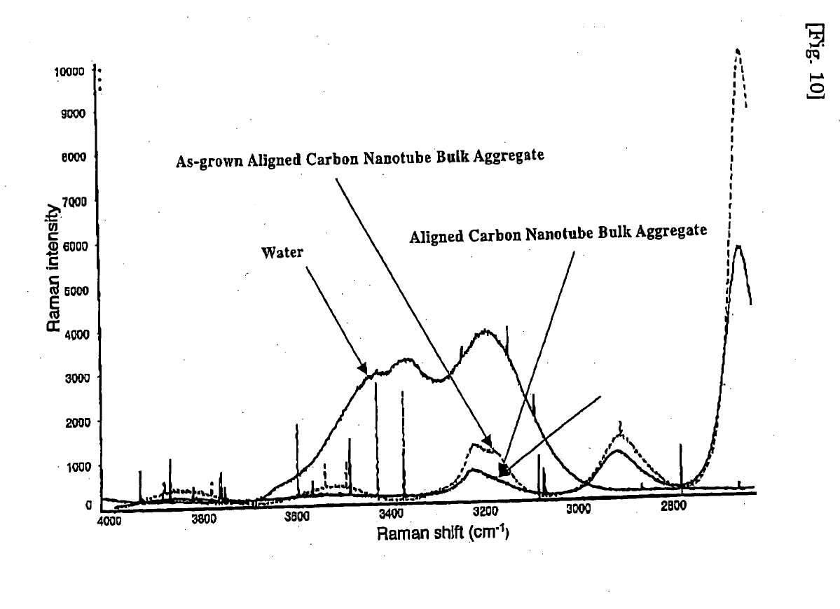

When plural aligned carbon nanotubes are exposed to the liquid, their aggregate may shrink a little and may much shrink when dried, thereby giving an aligned carbon nanotube bulk aggregate having a high density. In this case, the shrinkage is anisotropic, and one example is shown in FIG. 8. In FIG. 8, the left side shows an aligned carbon nanotube bulk aggregate produced according to the process of Non-Patent Document 1; and the right side shows one produced by exposing the aligned carbon nanotube bulk aggregate to water followed by drying. The alignment direction is z direction; and the plane vertical to the alignment direction has x direction and y direction defined therein. The shrinking image is shown in FIG. 9. Further, during exposure to solution, when weak external pressure is applied thereto, then the shape of the aligned carbon nanotube bulk aggregate may be controlled. For example, when the bulk aggregate is dipped In solution and dried while weak pressure is applied thereto in the x direction vertical to the alignment direction, then an aligned carbon nanotube bulk aggregate shrunk mainly in the x direction may be obtained. Similarly, when the solution dipping and drying is effected while weak pressure is applied obliquely to the alignment direction z, then a thin-filmy aligned carbon nanotube bulk aggregate shrunk mainly in the z direction may be obtained. The aligned carbon nanotube bulk aggregate may be processed according to the above process, after it is removed from the substrate on which it has grown, then it is placed on another substrate. In this case, it is possible to produce an aligned carbon nanotube bulk aggregate having high adhesiveness to any desired substrate. For example, in case where a thin-filmy aligned carbon nanotube bulk aggregate is formed on a metal, then it may have high electric conductivity adjacent to a metal electrode as in Example 4, and for example, it may be favorably utilized in an application of electroconductive materials for heater or capacitor electrodes. In this case, the pressure may be weak in such a level of picking up with tweezers, and it does not cause damage to the carbon nanotubes. Pressure alone could not compress the bulk aggregate to have the same degree of shrinkage not causing damage to the carbon nanotubes, and it is extremely important to use solution for producing a favorable aligned carbon nanotube bulk aggregate.

Raman data of the aligned carbon nanotube bulk aggregate produced by exposing plural aligned carbon nanotubes to water followed by drying are shown in FIG. 10 as one example. This drawing shows no water remaining in the dried bulk aggregate.

According to the process of the present invention, the shape of the aligned carbon nanotube bulk aggregate may be controlled in any desired manner depending on the patterning of the metal catalyst and on the growth of the carbon nanotubes. One example of a model of shape control is shown in FIG. 11.

This is an example of a thin-filmy aligned carbon nanotube bulk aggregate (relative to the diameter size of the carbon nanotubes, the aggregate (before exposed to liquid) is thin filmy but may be said bulky); and the thickness is thin relative to the height and the width, the width may be controlled in any desired length by patterning of the catalyst, the thickness may also be controlled in any desired thickness by patterning of the catalyst, and the height may be controlled by the growth of the plural aligned carbon nanotubes that constitute the aggregate (before exposed to liquid). When the aligned carbon nanotube aggregate before exposure to liquid is patterned in a predetermined shape and when it is exposed to liquid and dried, then a high-density aligned carbon nanotube bulk aggregate shrunk to a predetermined shrinkage (this may be previously estimated) and patterned in a predetermined shape may be produced.

The aligned carbon nanotube bulk aggregate of the present invention has an extremely large density and a high hardness as compared with conventional aligned carbon nanotube bulk aggregates, and further, the aligned carbon nanotube bulk aggregate patterned in a predetermined shape has various properties and characteristics such as ultra high purity, ultra heat conductivity, high specific surface area, excellent electronic and electric properties, optical properties, ultra mechanical strength, ultra high density, etc.; and therefore, they can be applied to various technical fields as mentioned below.

### (A) Heat Dissipation Material (Heat Dissipation Properties):

Articles that require heat radiation, for example, CPU serving as the core of computers of electronic articles are required to have rapider and more integrated computation capacity, and the degree of heat generation from CPU itself increasing more and more; and it is said that there may be a probability of limitation on the performance improvement of LSI in the near future. Heretofore, in heat dissipation at such a high heat generation density, known is a heat dissipation material produced by random-aligned carbon nanotubes embedded in polymer, which, however, is problematic in that its heat dissipation characteristics in the vertical direction are poor. Of the large-scaled aligned carbon nanotube bulk aggregate of the present invention, vertically-aligned ones have high heat dissipation properties and, in addition, they have high density and are long and aligned vertically; and accordingly, when they are utilized as heat dissipation materials, then they may drastically Increase their heat dissipation properties in the vertical direction, as compared with conventional articles.

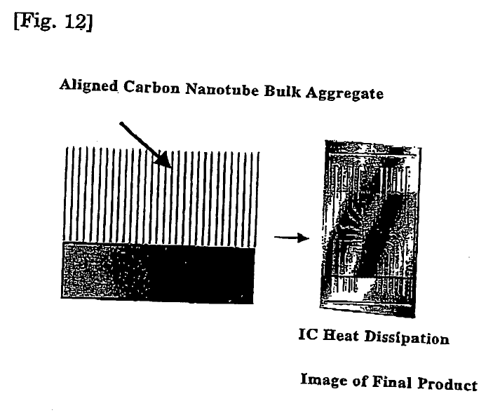

One example of the heat dissipation material is schematically shown in FIG. 12.

Not limited to electronic parts, the heat dissipation material of the present invention is applicable to other various articles that require heat dissipation, for example, electric products, optical products and machinery products.

### (B) Heat Conductors (Heat Conduction Properties):

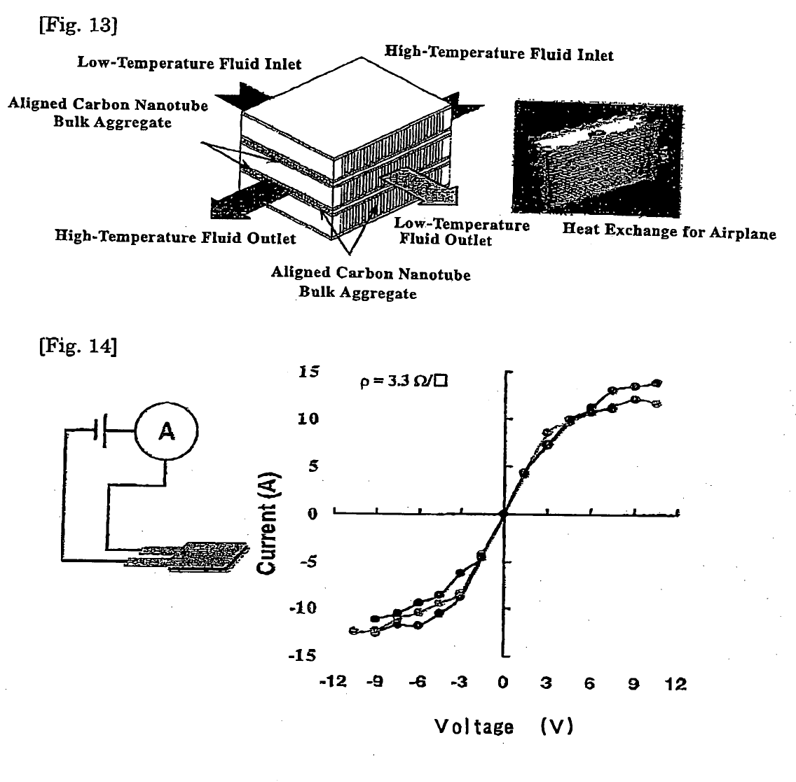

The aligned carbon nanotube bulk aggregate of the present invention has good heat conduction properties. The aligned carbon nanotube bulk aggregate having such excellent heat conductive properties may be worked into a heat conductor of a composite material containing it, thereby giving a high heat conduction material. For example, when it is applied to heat exchangers, driers, heat pipes, etc.; it may improve their performance. In case where the heat conductor is applied to heat exchangers for aerospace use, it may improve the heat exchange performance and may reduce the weight and the volume. In case where the heat conductor is applied to fuel cell cogenerations and micro-gas turbines, it may improve the heat exchange performance and the bent resistance. One example of a heat exchanger that utilizes the heat conductor is schematically shown in FIG. 13.

### (C) Electric Conductors (Electric Conductive Properties):

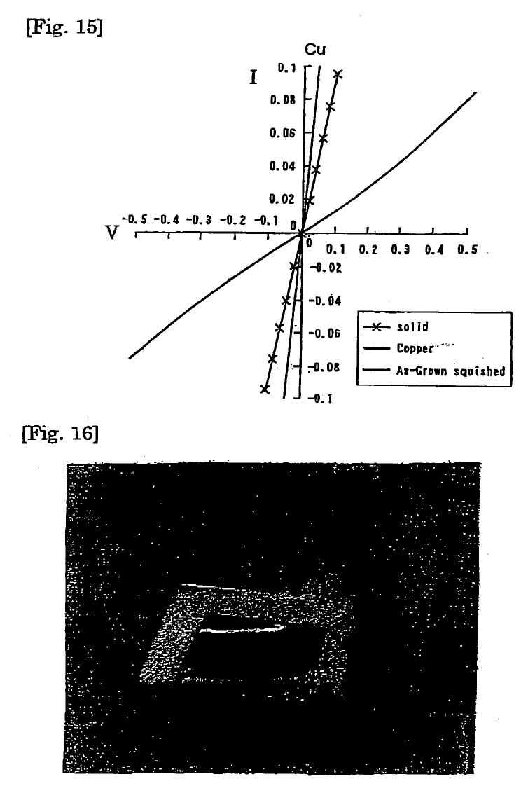

The aligned carbon nanotube bulk aggregate of the present invention has excellent electric properties such as electric conductivity. FIG. 14 shows current/voltage characteristics under high current application. FIG. 15 shows current/voltage characteristics under low current application.

The electric conductor of the present invention, or its wiring structure is usable as electric conductors or wiring structures in various articles that require electric conductivity, such as electric products, electronic products, optical products and machinery products.

For example, the above-mentioned aligned carbon nanotube bulk aggregate of the present invention, or a patterned aligned carbon nanotube bulk aggregate produced by patterning it in a predetermined shape may be used in place of copper wiring thereby contributing to better micropatterning and stabilization of devices because of its superiority in the high electric conductivity and the mechanical strength.

### (D) Supercapacitors, Secondary Batteries (Electric Properties):

A supercapacitor stores energy by charge movement therein, and is therefore characterized in that large current may run through it, it is durable to more than 100,000 charge-discharge cycles and its charging time is short. The important properties of supercapacitor are that its capacitance is large and its internal resistance is small. The capacitance is determined by the size of pores, and it is known that the capacitance could be the largest when the size of mesopores is from 3 to 5 nm or so, and this may be the same as the size of the carbon nanotubes that constitutes the aligned carbon nanotube bulk aggregate of the present invention. In the aligned carbon nanotube bulk aggregate of the present invention, or a patterned aligned carbon nanotube bulk aggregate produced by patterning it in a predetermined shape, all the constitutive elements may be optimized in parallel to each other and, in addition, since the surface area of the electrode and the like may be maximized, the internal resistance may be minimized, and therefore a high-performance supercapacitor can be produced.

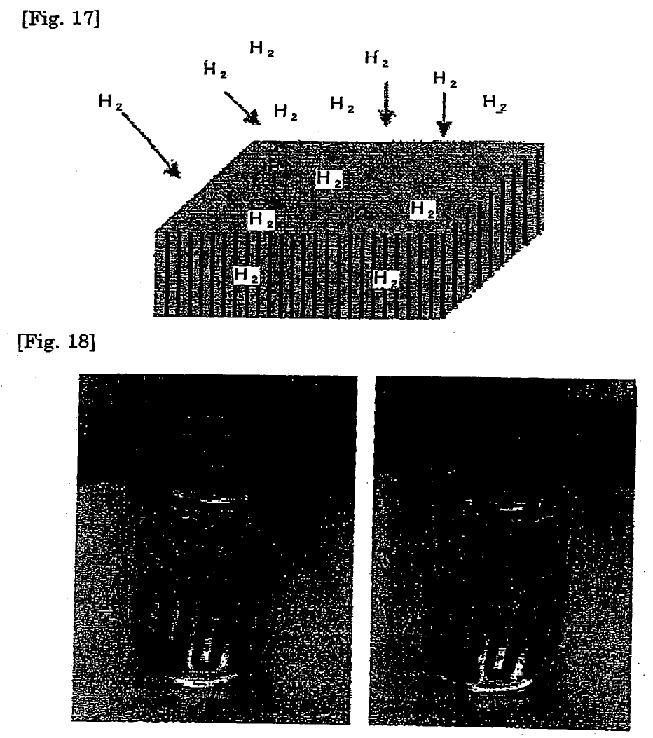

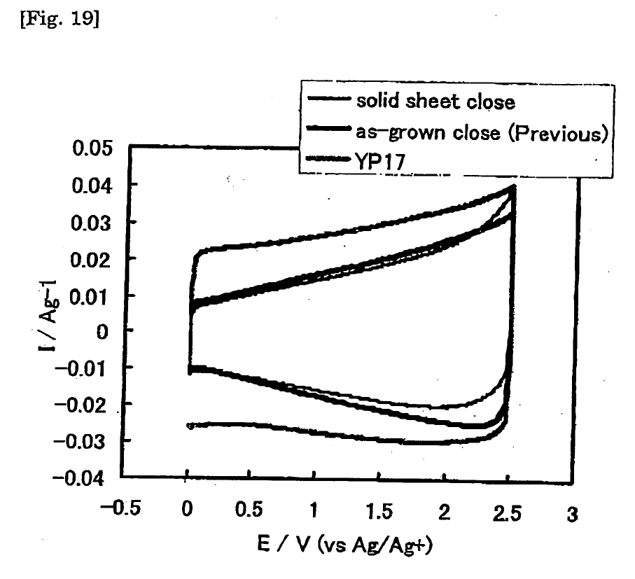

One example of a supercapacitor in which an aligned carbon nanotube bulk aggregate of the present invention, or a patterned aligned carbon nanotube bulk aggregate produced by patterning it in a predetermined shape is used as the constitutive material or the electrode material is schematically shown in FIG. 16.

Not limited to supercapacitors, the aligned carbon nanotube bulk aggregate of the present invention is applicable to constitutive materials for ordinary capacitors and also to electrode materials for secondary batteries such as lithium batteries, and electrode (negative electrode) materials for fuel cells or air cells, etc.

### (E) Gas Storage Material, Adsorbent (Absorbing Properties):

It is known that carbon nanotubes have a property of absorbing gag such as hydrogen or methane. Accordingly, the aligned carbon nanotube bulk aggregate of the present invention, having a large specific surface area, is expected to be applicable to storage and transportation of gas such as hydrogen or methane. FIG. 17 is a conceptual view schematically showing a case of application of the aligned carbon nanotube bulk aggregate of the present invention to a hydrogen storage. Like an active carbon filter, the bulk aggregate may absorb a harmful gas or substance, thereby to separate and purity a substance or gas.

### (F) Flexible Electrically Conductive Heaters:

The aligned carbon nanotube bulk aggregate of the present invention may be patterned in a thin film, and the patterned thin film is flexible and generates heat when a current on a predetermined level or more is applied thereto. Therefore, this is utilizable as flexible electrically conductive heaters. FIG. 18 shows examples of the aligned carbon nanotube bulk aggregate of the present invention applied to flexile electrically conductive heaters.

### EXAMPLES

Examples are shown below, and described in more detail.

Needless-to-say, the present invention should not be limited to the following Examples.

### Example 1

An aligned carbon nanotube aggregate was grown through CVD under the condition mentioned below.

Carbon compound: ethylene, feeding speed 100 seem
Atmosphere (gas) (Pa): helium/hydrogen mixed gas, feeding speed 1000 seem, one atmospheric pressure
Water vapor amount added (ppm): 150 ppm
Reaction temperature (° C.): 750° C.
Reaction time (min): 10 min
Metal catalyst (existing amount): thin iron film, thickness 1 nm
Substrate: silicon wafer

A sputtering vapor deposition device was used for disposing the catalyst on the substrate; and an iron metal having a thickness of 1 nm was disposed through vapor deposition.

Next, water droplets were dropped onto the upper surface of the aligned carbon nanotube aggregate produced in the above, and this operation was repeated until the aligned carbon nanotube aggregate could be finally completely enveloped in the water droplets. Thus exposed to water in that manner, this was put on a hot plate kept at 170° C. and dried thereon, thereby giving an aligned carbon nanotube bulk aggregate of the present invention.

The properties of the obtained aligned carbon nanotube bulk aggregate are shown in Table 1, as compared with the properties of the aligned carbon nanotube bulk aggregate as-grown.

TABLE 1

| | Aligned Bulk | Aligned Bulk |
|---|---|---|
| | Aggregate | Aggregate |
| | as-grown | of Example 1 |
| Density (g/cm³) | 0.029 | 0.57 |
| Nanotube Density | 4.3 × 10¹¹ | 8.3 × 10¹² |
| (number of nanotubes/cm²) | | |
| Area per one nanotube | 234 nm² | 11.9 nm² |
| Lattice Constant | 16.4 nm | 3.7 nm |
| Coating Ratio | about 3% | 53% |
| Vickers Hardness | about 0.1 | 7 to 10 |

The purity of the aligned carbon nanotube bulk aggregate of Example 1 was 99.98%.

### Example 2

An aligned carbon nanotube bulk aggregate of Example 2 was produced in the same manner as in Example 1, for which, however, the aligned carbon nanotube bulk aggregate as-grown was exposed to ethanol but not to water. Like that of Example 1, the aligned carbon nanotube bulk aggregate also had high density and its other properties were also good.

### Example 3

In Example 1, the aligned carbon nanotube bulk aggregate as-grown was exposed to any of alcohols (isopropanol, methanol), acetone (acetone), hexane, toluene, cyclohexane or DMF (dimethylformamide) in place of water, and then dried. Like that in Example 1, the obtained products all had high density and their other properties were also good.

### Example 4

### Thin Film

An aligned carbon nanotube aggregate was grown through CVD under the condition mentioned below.

Carbon compound: ethylene, feeding speed 100 seem Atmosphere (gas) (Pa): helium/hydrogen mixed gas, feeding speed 1000 seem, one atmospheric pressure

Water vapor amount added (ppm): 150 ppm
Reaction temperature (° C.): 750° C.
Reaction time (min): 10 min
Metal catalyst (existing amount): thin iron film, thickness 1 μm
Substrate: silicon wafer

A sputtering vapor deposition device was used for disposing the catalyst on the substrate; and an iron metal having a thickness of 1 nm was disposed through vapor deposition.

Next, the aligned carbon nanotube bulk aggregate produced in the above was peeled from the substrate on which it was grown, using tweezers or the like, and put on a copper substrate, on which this was exposed to water under weak pressure applied in the direction oblique to the alignment direction z, and then fixed therein with tweezers. With the weak pressure given thereto, this was put on a hot plate kept at 170° C., and dried thereon, whereby this was shrunk mainly in the z direction Thus, a thin-filmy aligned carbon nanotube bulk aggregate of the present invention was produced.

The density of the thin-filmy aligned carbon nanotube bulk aggregate was about 0.6 g/cm³ and the size of the thin film was 1 cm×1 cm×height 70 μm.

### Example 5

### Columnar Article

An aligned carbon nanotube aggregate was grown through CVD under the condition mentioned below.

Carbon compound: ethylene, feeding speed 100 sccm
Atmosphere (gas) (Pa): helium/hydrogen mixed gas, feeding speed 1000 sccm, one atmospheric pressure
Water vapor amount added (ppm): 150 ppm
Reaction temperature (° C.): 750° C.
Reaction time (min): 10 min
Metal catalyst (existing amount): thin Iron film, thickness 1 nm
Substrate: silicon wafer

A sputtering vapor deposition device was used for disposing the catalyst on the substrate; and an iron metal having a thickness of 1 nm was disposed through vapor deposition. The catalyst was patterned columnarly, in which the diameter of each column was 50 μm.

Next, using tweezers, the surface of the substrate was wetted with a liquid so that the aligned carbon nanotube bulk aggregate produced in the above could be dipped in and exposed to the liquid from the point at which it is contacted with the substrate, and then this was put on a hot plate kept at 70° C. and dried thereon, whereby a columnarly-patterned aligned carbon nanotube bulk aggregate of the present invention was thus produced.

The density of the columnar aligned carbon nanotube bulk aggregate was about 0-6 g/cm³, and the size of each column was diameter 11 μm×height 1000 μm.

### Example 6

### Supercapacitor

The aligned carbon nanotube bulk aggregate obtained in Example 4 was demonstrated for evaluation of its properties as a capacitor electrode. A test cell was constructed, n which an electrode material comprising 2 mg of the aligned carbon nanotube bulk aggregate was used as the working electrode, and Ag/Ag+ was as the reference electrode. As the electrolytic solution, used as a propylene carbonate PC-type electrolytic solution. Thus constructed, the constant current charge/discharge characteristic of the test cell was determined. The cyclic voltamography data are shown in FIG. 19. This graph confirms that the aligned carbon nanotube bulk aggregate of Example 4 serves as a capacitor material.

### Example 7

50 mg of the aligned carbon nanotube bulk aggregate obtained in Example 1 was analyzed for the liquid nitrogen adsorption/desorption isothermal curve at 77 K, using Nippon Bell's BELSORP-MINI (adsorption equilibrium time wits 600 seconds). The overall adsorption was extremely large value (742 ml/g). The specific surface area was computed from the adsorption/desorption isothermal curve, and was 1100 m²/g.

50 mg of other samples were torn off from the same aligned carbon nanotube bulk aggregate, using tweezers, and put on an alumina tray at regular intervals, and then introduced into a muffle furnace. This was heated up to 500° C. at 1° C./min, and then left at 500° C. for 1 minute in the presence of oxygen (concentration about 20%). After the heat treatment, the weight of each sample was 50 mg, and the samples could still have the original weight even after the heat treatment. Like in the above, the heat-treated samples were analyzed for the liquid nitrogen adsorption/desorption isothermal curves (FIG. 4). As a result, the specific surface area was estimated as nearly 1900 m²/g. As compared with the sample before heat treatment, the heat-treated sample had a larger specific surface area, and it is suggested that the top ends of the carbon nanotubes could be opened through the heat treatment. In the drawing, P indicates an adsorption equilibrium pressure; and P₀ indicates a saturated water vapor pressure.

### Example 8

### Gas Storage

100 mg of the aligned carbon nanotube bulk aggregate obtained in Example 1 was analyzed for hydrogen absorption, using Nippon Bell's high-pressure single component adsorption meter (FMS-AD-RI). As a result, the hydrogen absorption was 0.4% by weight at 10 MPa and 25° C. Regarding the releasing process, the sample underwent reversible gas release depending only on pressure.

### Example 9

### Heat Conductor, Heat Dissipation Material

The aligned carbon nanotube bulk aggregate obtained in Example 1 was analyzed for the heat diffusion ratio to thereby determine the heat conductivity thereof. The test temperature was room temperature, and the size of the sample was 1 cm×1 cm. The sample was analyzed as three forms, the sample alone, and two others each with a glass plate disposed above and below the sample. The heat diffusion ratio was determined by a CF method and zero extrapolation for the pulse heating energy dependency.

In vacuum, the sample temperature was nearly constant and the thermal loss effect was small; and in air, the sample temperature lowered and the heat loss effect was large. These confirm the heat dissipation effect of the aligned carbon nanotube bulk aggregate. Accordingly, the aligned carbon nanotube bulk aggregate is expected to be useful as a heat conductor and a heat dissipation material.

### Example 10

### Electric Conductor

The aligned carbon nanotube bulk aggregate obtained in Example 4 was cut into a piece having a size of 2 cm×2 cm×height 70 μm; and copper plates were kept in contact with both sides thereof, the sample was analyzed for the electric transporting characteristic according to a two-terminal method using a prober, Cascade Microtech's Sumit-12101B-6 and a semiconductor analyzer, Agilent's 4155C. The results are shown in FIGS. 14 and 15. From these drawings, the aligned carbon nanotube bulk aggregate of the above Example is expected to be useful as an electric conductor.

### Example 11

### Flexible Electrically Conductive Heater

The aligned carbon nanotube bulk aggregate obtained in Example 4 was shaped into a structure as in FIG. 18, fitted around a glass bottle filled with water, and a power of 15 W (0.1 A×150 V) was applied thereto. As a result, it was confirmed that the structure could be usable as a heater.

1-49. (canceled)

50. An aligned carbon nanotube bulk aggregate in which plural carbon nanotubes are aligned in a predetermined direction and which has a density of from 0.2 to 1.5 g/cm³.

51. The aligned carbon nanotube bulk aggregate as claimed in claim 50, wherein the carbon nanotubes are single-walled carbon nanotubes.

52. The aligned carbon nanotube bulk aggregate as claimed in claim 50, wherein the carbon nanotubes are double-walled carbon nanotubes.

53. The aligned carbon nanotube bulk aggregate as claimed in claim 50, wherein the carbon nanotubes are a mixture of single-walled carbon nanotubes and double-walled or more multi-walled carbon nanotubes.

54. The aligned carbon nanotube bulk aggregate as claimed in claim 50, which has a purity of at least 98 mass %.

55. The aligned carbon nanotube bulk aggregate as claimed in claim 50, which has a specific surface area of from 600 to 2600 m²/g.

56. The aligned carbon nanotube bulk aggregate as claimed in claim 50, which is unopened and which has a specific surface area of from 600 to 1300 m²/g.

57. The aligned carbon nanotube bulk aggregate as claimed in claim 50, which is opened and which has a specific surface area of from 1300 to 2600 m²/g.

58. The aligned carbon nanotube bulk aggregate as claimed in claim 50, which is a mesoporous material having a packing ratio of from 5 to 50%.

59. The aligned carbon nanotube bulk aggregate as claimed in claim 50, which has a mesopore diameter of from 1.0 to 5.0 nm.

60. The aligned carbon nanotube bulk aggregate as claimed in claim 50, which has a Vickers hardness of from 5 to 100 HV.

61. The aligned carbon nanotube bulk aggregate as claimed in claim 50, which is vertically aligned or horizontally aligned on a substrate.

62. The aligned carbon nanotube bulk aggregate as claimed in claim 50, which is aligned on a substrate in the direction oblique to the substrate surface.

63. The aligned carbon nanotube bulk aggregate as claimed in claim 50, which has anisotropy between the alignment direction and the direction vertical thereto, in at least any of optical properties, electric properties, mechanical properties and thermal properties.

64. The aligned carbon nanotube bulk aggregate as claimed in claim 50, wherein the degree of anisotropy between the alignment direction and the direction vertical thereto is at most ⅕ in terms of the ratio of the small value to the large value.

65. The aligned carbon nanotube bulk aggregate as claimed in claim 50, wherein the intensity ratio of any of the (100), (110) and (002) peaks in the alignment direction and in the direction vertical thereto in X-ray diffraction is from ½ to 1/100 in terms of the ratio of the small value to the large value.

66. The aligned carbon nanotube bulk aggregate as claimed in claim 50, wherein the shape of the bulk aggregate is patterned in a predetermined shape.

67. The aligned carbon nanotube bulk aggregate as claimed in claim 66, wherein the shape is a thin film.

68. The aligned carbon nanotube bulk aggregate as claimed in claim 66, wherein the shape is a columnar one having a circular, oval or n-angled cross section (n is an integer of at least 3).

69. The aligned carbon nanotube bulk aggregate as claimed in claim 66, wherein the shape is a block.

70. The aligned carbon nanotube bulk aggregate as claimed in claim 66, wherein the shape is a needle-like one.

71. A process for producing an aligned carbon nanotube bulk aggregate through chemical vapor deposition (CVD) of carbon nanotubes in the presence of a metal catalyst, wherein plural carbon nanotubes are grown, as aligned, in a reaction atmosphere, and then the resulting plural carbon nanotubes are exposed to liquid and dried thereby giving an aligned carbon nanotube bulk aggregate having a density of from 0.2 to 1.5 g/m³.

72. The process for producing an aligned carbon nanotube bulk aggregate as claimed in claim 71, which is for producing an aligned carbon nanotube bulk aggregate where the carbon nanotubes are single-walled carbon nanotubes.

73. The process for producing an aligned carbon nanotube bulk aggregate as claimed in claim 71, which is for producing an aligned carbon nanotube bulk aggregate where the carbon nanotubes are double-walled carbon nanotubes.

74. The process for producing an aligned carbon nanotube bulk aggregate as claimed in claim 71, which is for producing an aligned carbon nanotube bulk aggregate where the carbon nanotubes are a mixture of single-walled carbon nanotubes and double-walled or more multi-walled carbon nanotubes.

75. The process for producing an aligned carbon nanotube bulk aggregate as claimed in claim 71, which is for producing an aligned carbon nanotube bulk aggregate having a purity of at least 98 mass %.

76. The process for producing an aligned carbon nanotube bulk aggregate as claimed in claim 71, which is for producing an aligned carbon nanotube bulk aggregate having a specific surface area of from 600 to 2600 m²/g.

77. The process for producing an aligned carbon nanotube bulk aggregate as claimed in claim 71, which is for producing an aligned carbon nanotube bulk aggregate that is unopened and has a specific surface area of from 600 to 1300 m²/g.

78. The process for producing an aligned carbon nanotube bulk aggregate as claimed in claim 71, which is for producing an aligned carbon nanotube bulk aggregate that is opened and has a specific surface area of from 1300 to 2600 m²/g.

79. The process for producing an aligned carbon nanotube bulk aggregate as claimed in claim 71, which is for producing an aligned carbon nanotube bulk aggregate that has anisotropy between the alignment direction and the direction vertical thereto, in at least any of optical properties, electric properties, mechanical properties and thermal properties.

80. The process for producing an aligned carbon nanotube bulk aggregate as claimed in claim 71, which is for producing an aligned carbon nanotube bulk aggregate of such that the degree of anisotropy between the alignment direction and the direction vertical thereto is at most ⅕ in terms of the ratio of the small value to the large value.

81. The process for producing an aligned carbon nanotube bulk aggregate as claimed in claim 71, which is for producing an aligned carbon nanotube bulk aggregate of such that the intensity ratio of any of the (100), (110) and (002) peaks in the alignment direction and in the direction vertical thereto in X-ray diffraction is from ½ to 1/100 in terms of the ratio of the small value to the large value.

82. The process for producing an aligned carbon nanotube bulk aggregate as claimed in claim 71, which is for producing an aligned carbon nanotube bulk aggregate as patterned in any desired shape.

83. The process for producing an aligned carbon nanotube bulk aggregate as claimed in claim 82, which is for producing an aligned carbon nanotube bulk aggregate having a thin filmy shape.

84. The process for producing an aligned carbon nanotube bulk aggregate as claimed in claim 82, which is for producing an aligned carbon nanotube bulk aggregate having a columnar shape that has a circular, oval or n-angled cross section (n is an integer of at least 3).

85. The process for producing an aligned carbon nanotube bulk aggregate as claimed in claim 82, which is for producing an aligned carbon nanotube bulk aggregate having a block shape.

86. The process for producing an aligned carbon nanotube bulk aggregate as claimed in claim 82, which is for producing an aligned carbon nanotube bulk aggregate having a needle-like shape.

87. A heat dissipation material comprising the aligned carbon nanotube bulk aggregate of claim 50.

88. An article provided with the heat dissipation material of claim 87.

89. A heat conductor comprising the aligned carbon nanotube bulk aggregate of claim 50.

90. An article provided with the heat conductor of claim 89.

91. An electric conductor comprising the aligned carbon nanotube bulk aggregate of claim 50.

92. An article provided with the electric conductor of claim 91.

93. An electrode material comprising the aligned carbon nanotube bulk aggregate of claim 50.

94. A cell wherein the electrode comprises the electrode material of claim 93.

95. A capacitor or supercapacitor wherein the electrode material comprises the aligned carbon nanotube bulk aggregate of claim 50.

96. An adsorbent comprising the aligned carbon nanotube bulk aggregate of claim 50.

97. A gas absorbent comprising the aligned carbon nanotube bulk aggregate of claim 50.

98. A flexible electrically conductive heater comprising the aligned carbon nanotube bulk aggregate of claim 50.
